(19) United States
(12) Patent Application Publication
(10) Pub. No.: US 2004/0229427 A1
(43) Pub. Date: Nov. 18, 2004

(54) Semiconductor device with capacitor

(75) Inventors: Kazutoshi Wakao, Hyogo (JP); Junichi Tsuchimoto, Hyogo (JP); Yutaka Inaba, Hyogo (JP); Kazuhiro Aihara, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/690,571

(22) Filed: Oct. 23, 2003

(30) Foreign Application Priority Data
May 16, 2003 (JP) 2003-139267(P)

(51) Int. Cl. H01L 21/8234

(52) U.S. Cl. 438/253; 438/396; 438/255

(57) ABSTRACT

A pointed shape may be present on the top end of the capacitor bottom (lower) electrode of a cylindrical capacitor. To cover this pointed end, a two-layer dielectric film of a capacitor dielectric film and another capacitor dielectric film is formed. As a result, while the capacitor bottom electrode has a pointed shape on its top end, the dielectric film covering the portion having a pointed shape has a greater thickness than the dielectric film covering the other parts of the vertical portion. Thus, even if the portion with a pointed shape on the capacitor bottom electrode has a concentration of electric field, the dielectric film exhibits a sufficient insulation performance to prevent leakage current. In this way, a semiconductor device is provided with an improved property of a capacitor dielectric film by the reduction of the risk of generating a leakage current in the capacitor dielectric film.

### BACKGROUND OF THE INVENTION

1. Field of the Invention

The present invention relates to a semiconductor device with a capacitor and a method for manufacturing the same.

2. Description of the Background Art

Semiconductor devices such as DRAMs (Dynamic Random Access Memories) are known that have, above a semiconductor substrate, a cylindrical capacitor provided with capacitor electrodes having a vertical portion that extends perpendicularly to the main surface of the semiconductor substrate.

In such conventional capacitors, however, a pointed shape is often formed on the top end of the vertical portion of a capacitor lower electrode. Further, when a capacitor lower electrode is formed by metal organic chemical vapor deposition, the surface of the hole defined by the capacitor lower electrode may have a portion thereon with irregularities having pointed tips. In a capacitor with a capacitor dielectric film stacked on the top end having such a pointed shape or on a portion having irregularities with pointed tips, leakage current may occur in the capacitor dielectric film formed on the portion at the top end with such a pointed shape or on the portion having irregularities with pointed tips.

### SUMMARY OF THE INVENTION

An object of the present invention is to provide a semiconductor device that enables the reliability of the dielectric film of a capacitor to be improved.

A semiconductor device according to the present invention includes a semiconductor substrate, a capacitor lower electrode having a vertical portion extending substantially perpendicularly to a main surface of the semiconductor substrate, a capacitor dielectric film covering a surface of the vertical portion, and a capacitor upper electrode covering a surface of the capacitor dielectric film. Additionally, the thickness of the portion of the capacitor dielectric film formed on top of the vertical portion is greater than that of the portion formed on a side of the vertical portion.

According to the structure described above, leakage current is less likely to occur in the capacitor dielectric film in the portion on top of the vertical portion. As a result, the capacitor dielectric film is more reliable.

A method for manufacturing a semiconductor device according to an aspect of the present invention includes the following steps: initially, above a semiconductor substrate, a film is formed that is to be a capacitor lower electrode with a vertical portion extending perpendicularly to a main surface of the semiconductor substrate; next, a film is formed that is to be a capacitor dielectric film to cover a surface of the vertical portion; subsequently, sputtering or plasma chemical vapor deposition of a dielectric is performed from above the film that is to be the capacitor dielectric film in order to adhere a dielectric film on a surface of the film that is to be the capacitor dielectric film above the vertical portion; a film that is to be a capacitor upper electrode is then formed to cover a surface of the film that is to be the capacitor dielectric film and of the additional dielectric film.

The method disclosed above allows an insulating film to be adhered on a surface of a capacitor dielectric film above the vertical portion by sputtering. As a result, the film that functions as the capacitor dielectric film has a greater thickness above the vertical portion. Accordingly, while the top end of the vertical portion of the capacitor lower electrode has a pointed shape, the dielectric film above the vertical portion has a greater thickness than the dielectric film covering the other parts of the vertical portion. Thus, leakage current is less likely to occur in the capacitor dielectric film above the vertical portion. Consequently, the capacitor dielectric film is more reliable.

A method for manufacturing a semiconductor device according to another aspect of the present invention includes the following steps: initially, above a semiconductor substrate, a film is formed that is to be a capacitor lower electrode, made of ruthenium, with a vertical portion extending substantially perpendicularly to a main surface of the semiconductor substrate; the film that is to be the capacitor lower electrode is then annealed in a reducing environment at a temperature ranging from 500 to 950° C., under a pressure ranging from 1 Torr to atmospheric pressure, for one minute or longer. Next, a film that is to be a capacitor dielectric film is formed to cover a surface of the film that is to be the capacitor lower electrode, which has been annealed. A film that is to be a capacitor upper electrode is then formed to cover a surface of the film that is to be the capacitor dielectric film.

The above-described method allows ruthenium to be melted due to annealing. Accordingly, even if the top end of the vertical portion of the capacitor lower electrode of ruthenium has a pointed shape, the pointed shape of the top end is changed to a rounded shape due to annealing. Thus, since the rounded portion does not have concentration of electric field, leakage current is less likely to occur in the capacitor dielectric film. As a result, the capacitor dielectric film is more reliable.

A method for manufacturing a semiconductor device according to still another aspect of the present invention includes the following steps: initially, an interlayer insulation film is formed above a semiconductor substrate; next, a hole penetrating the interlayer insulation film from top to bottom is formed; subsequently, a film that is to be a capacitor lower electrode made of ruthenium is formed over the side surface of the hole by metal organic chemical vapor deposition; the interlayer insulation film is then removed, leaving the film that is to be the capacitor lower electrode; then, the film that is to be the capacitor lower electrode is annealed in a reducing environment at a temperature from 650 to 950° C. under a pressure ranging from 1 Torr to atmospheric pressure for one minute or longer; a film that is to be a capacitor dielectric film is then formed to cover a surface of the film that is to be the capacitor lower electrode, which has been annealed; a film that is to be a capacitor upper electrode is then formed to cover a surface of the film that is to be the capacitor dielectric film.

The above-described method provides an effect similar to that obtained by the other aspect of the method for producing a semiconductor device described above. Further, a semiconductor device of the present aspect provides the following advantage:

A film that is to be a capacitor lower electrode formed by metal organic chemical vapor deposition has irregularities with pointed tips on its surface. The portion that has irregularities with pointed tips often has concentration of electric field. According to the present aspect of the method for manufacturing a semiconductor device, however, the capacitor lower electrode with irregularities with pointed tips is annealed in a prescribed condition. As a result, the portion with irregularities is melted, such that their tips have a smooth, curved surface. In this way, concentration of electric field in a capacitor bottom electrode caused by irregularities with pointed tips is suppressed. Leakage current is thus prevented in the capacitor dielectric film.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram depicting a structure of a semiconductor device according to a first embodiment.

FIGS. 2-7 illustrate a method for manufacturing a semiconductor device according to the first embodiment.

FIG. 8 is a diagram depicting a structure of a semiconductor device according to a second embodiment.

FIGS. 9-11 illustrate a method for manufacturing a semiconductor device according to the second embodiment.

FIG. 12 is a photographic picture showing an upper surface of a capacitor lower electrode when a method for manufacturing a semiconductor device according to the second embodiment has not been used.

FIG. 13 is a photographic picture showing an upper surface of a capacitor lower electrode when the method for manufacturing a semiconductor device according to the second embodiment has been used.

FIG. 14 is a diagram depicting a structure of a semiconductor device according to a third embodiment.

FIGS. 15-20 illustrate a method for manufacturing a semiconductor device according to the third embodiment.

FIG. 21 is a photographic view showing an upper surface of a capacitor lower electrode when a method for manufacturing a semiconductor device according to the third embodiment has not been used.

FIG. 22 is a photographic view showing an upper surface of a capacitor lower electrode when the method for manufacturing a semiconductor device according to the third embodiment has been used.

### DESCRIPTION OF THE PREFERRED EMBODIMENTS

A semiconductor device and a method for manufacturing the same according to the embodiments of the present invention will be described below in conjunction with the accompanying drawings.

First Embodiment

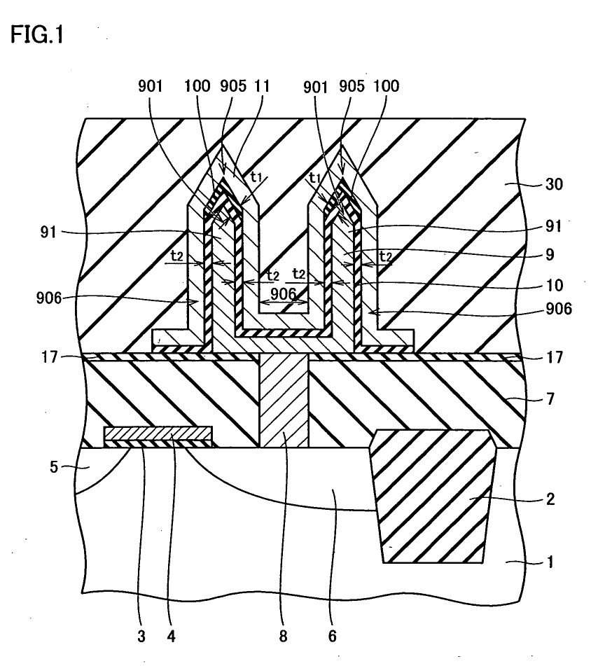

First, a semiconductor device according to a first embodiment and a method for manufacturing the same will be described with reference to FIGS. 1 to 7.

A structure of a semiconductor device according to the first embodiment is described with reference to FIG. 1. As shown in FIG. 1, a semiconductor device of the present embodiment has a structure as described below:

A semiconductor substrate 1 has an element isolating insulation film 2 formed therein. A gate insulation film 3 and a gate electrode 4 are provided on semiconductor substrate 1 in an element forming region surrounded by element isolating insulation film 2. On either side of gate insulation film 3 and gate electrode 4, source/drain regions 5, 6 are provided in semiconductor substrate 1.

Further, an interlayer insulation film 7 covers gate insulation film 3, gate electrode 4, source/drain regions 5, 6 and element isolating insulation film 2. A silicon nitride film 17 is formed on interlayer insulation film 7. A contact plug 8 penetrates silicon nitride film 17 and interlayer insulation film 7 from top to bottom and is connected to source/drain region 6.

Also, on silicon nitride film 17, a capacitor bottom (lower) electrode 9 is formed in contact with contact plug 8. Capacitor bottom electrode 9 is made of ruthenium. Capacitor bottom electrode 9 is part of a cylindrical capacitor and has a vertical portion 91 that extends substantially perpendicularly to a main surface of semiconductor substrate 1. Also, a top end 901 of vertical portion 91 of capacitor bottom electrode 9 is pointed.

Further, a capacitor dielectric film 10 covers a surface of capacitor bottom electrode 9. Above vertical portion 91 of capacitor bottom electrode 9, a dielectric film 100 is stacked on dielectric film 10. This two-layer structure of dielectric film 10 and dielectric film 100 forms the capacitor dielectric film.

A capacitor top (upper) electrode 11 covers a surface of dielectric films 10, 100. Further, an interlayer insulation film 30 is formed such that silicon nitride film 17 and capacitor top electrode 11 are embedded therein.

In a semiconductor device of the present embodiment described above, a film thickness t¹ of the capacitor dielectric film for part 905 which is located on top of capacitor bottom electrode 9 is greater than a film thickness t² of part 906 which is located on a side of capacitor bottom electrode 9. That is, the film thickness of the portion constructed of capacitor dielectric film 10 and capacitor dielectric film 100 formed above capacitor bottom electrode 9 is greater than the film thickness of capacitor dielectric film 10 only, which is formed along the side surface of capacitor bottom electrode 9.

Therefore, even if top end 901 of capacitor bottom electrode 9 has a pointed portion, leak current is less likely to occur in the capacitor dielectric film formed on portion 905 located above such a pointed portion. Thus, the capacitor dielectric film is more reliable.

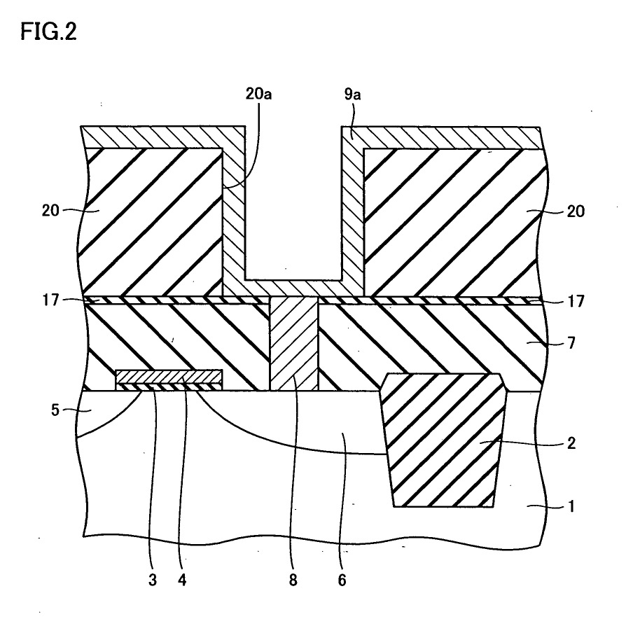

Now, a method for manufacturing a semiconductor device according to the present embodiment will be described with reference to FIGS. 2 to 7. As shown in FIG. 2, the structure below silicon nitride film 17 is exactly the same as that of the semiconductor device of FIG. 1, and will not be described again.

In FIG. 2, after silicon nitride film 17 and contact plug 8 are formed, an interlayer insulation film 20 is formed to cover silicon nitride film 17 and contact plug 8. A hole 20a is made that penetrates this interlayer insulation film 20 from top to bottom, exposing a surface of contact plug 8.

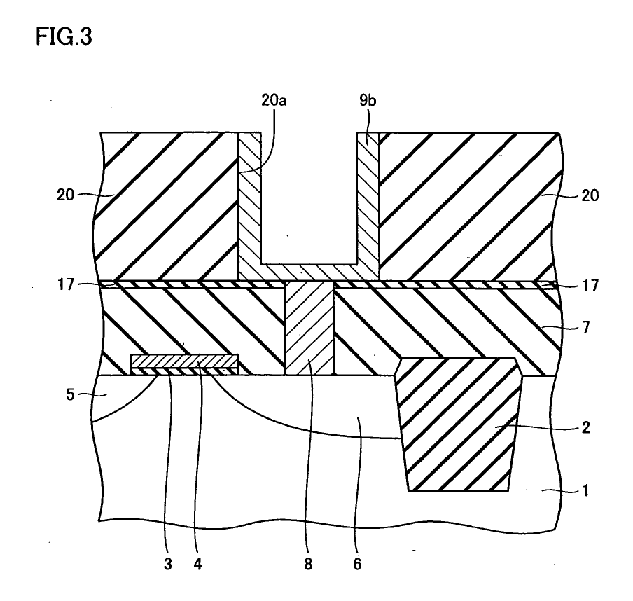

Next, a conductive layer 9a of ruthenium is formed on the top surface of interlayer insulation film 20 and on the side and bottom surfaces of hole 20a, using, for example, CVD (Chemical Vapor Deposition) or sputtering. Conductive layer 9a is a film that will eventually be a conductive layer 9b and ultimately capacitor bottom electrode 9, as described later. Next, conductive layer 9a formed on the top surface of interlayer insulation film (silicon oxide) 20 is removed by CMP (Chemical Mechanical Polishing). This provides a structure as shown in FIG. 3. In the structure illustrated in FIG. 3, conductive layer 9b has been formed on the side and bottom of hole 20a. This conductive layer 9b is a film that will ultimately be capacitor bottom electrode 9.

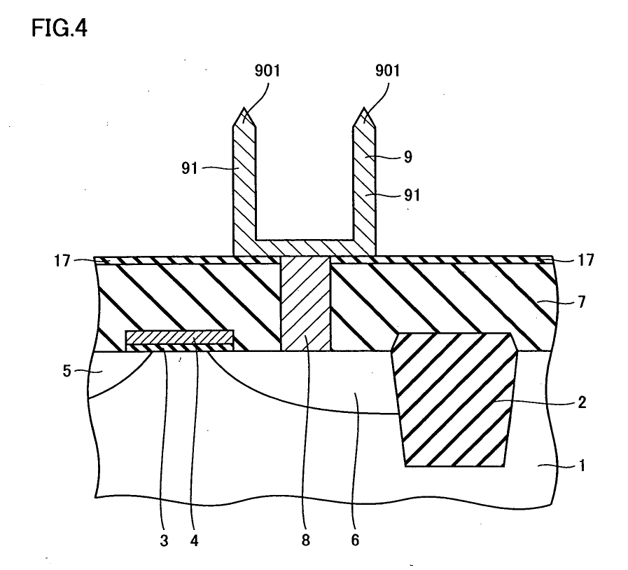

Next, interlayer insulation film 20 of silicon oxide is wet-etched by hydrofluoric acid to form capacitor bottom electrode 9 as shown in FIG. 4, while silicon nitride film 17 is not etched away by wet-etching with hydrofluoric acid. Consequently, only capacitor bottom electrode 9 remains on silicon nitride film 17. In addition, wet-etching with hydrofluoric acid creates a pointed shape on top end 901 of vertical portion 91 of capacitor bottom electrode 9, made of ruthenium.

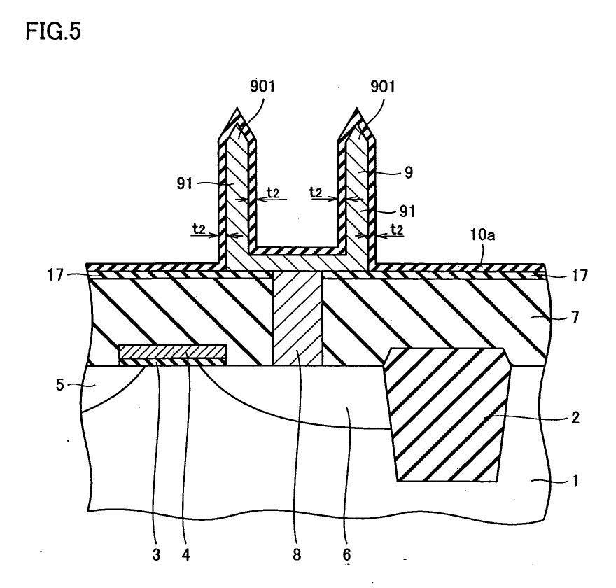

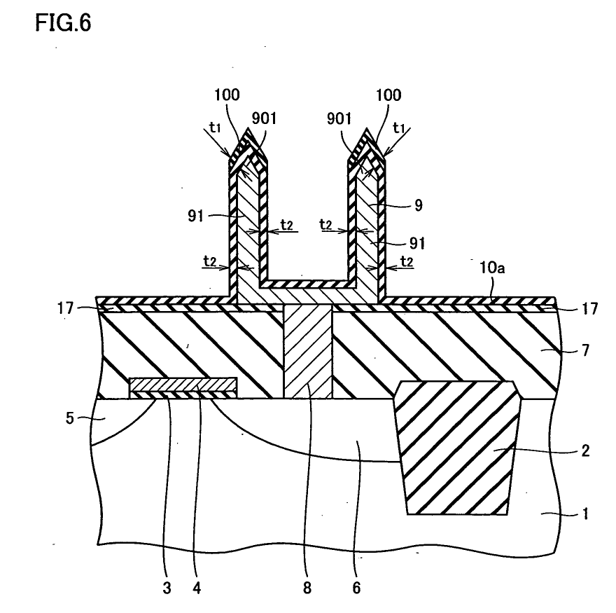

Next, as shown in FIG. 5, dielectric film 10a is formed on the surface of silicon nitride film 17 and that of capacitor bottom electrode 9 by CVD and the like. As shown in FIG. 6, dielectric film 100 is then adhered on dielectric film 10a from above by sputtering or plasma CVD, which do not cause a surface to be entirely coated.

Dielectric film 100 has only a small adhesion to dielectric film 10a, such that using either sputtering or plasma CVD causes dielectric film 100 to be adhered only to the upper surface of dielectric film 10a on vertical portion 91 of the film that is to be capacitor bottom electrode 9. Accordingly, the capacitor dielectric film has a two-layer structure only on top of vertical portion 91 of the film that is to be capacitor bottom electrode 9. Dielectric film 10a and dielectric film 100 may be insulating films of one and the same composition, or those of different compositions. It should be noted that, for example, tantalum oxide (Ta₂O₅) or barium strontium titanate can be used as dielectric film 10a and dielectric film 100.

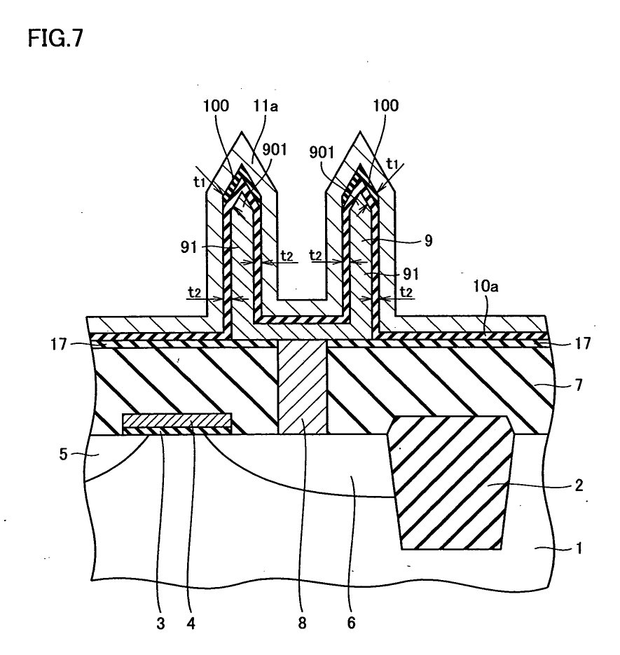

Then, as shown in FIG. 7, a conductive layer 11a is formed that is made of, for example, ruthenium or doped polycrystalline silicon, covering the surface of dielectric film 10a and that of dielectric film 100. Periphery of the portion that is to be a capacitor is then covered by a resist. The resist is used as a mask to remove an unnecessary portion of dielectric film 10a and that of conductive layer 11a.

The resist is then removed, forming a capacitor including capacitor bottom electrode 9, capacitor dielectric film 10, 100 and capacitor top electrode 11, as shown in FIG. 1. An interlayer insulation film 30 is then formed to cover silicon nitride film 17 and conductive layer 11a, resulting in the structure of FIG. 1.

Referring to FIGS. 5 and 6, by using the method for manufacturing a semiconductor device according to the present embodiment described above, dielectric film 100 is adhered only to upper surface on dielectric film 10 located on top end 91 of capacitor bottom electrode 9 by sputtering or plasma CVD, which do not provide good adhesion of a film.

Therefore, only the film thickness t₁ of capacitor dielectric film 10, 100 on top of the pointed portion of capacitor bottom electrode 9 is increased. As a result, leakage current is less likely to occur in a capacitor dielectric film of the part 905, which is located above the pointed portion of capacitor bottom electrode 9. Accordingly, a property of a semiconductor device is improved.

Second Embodiment

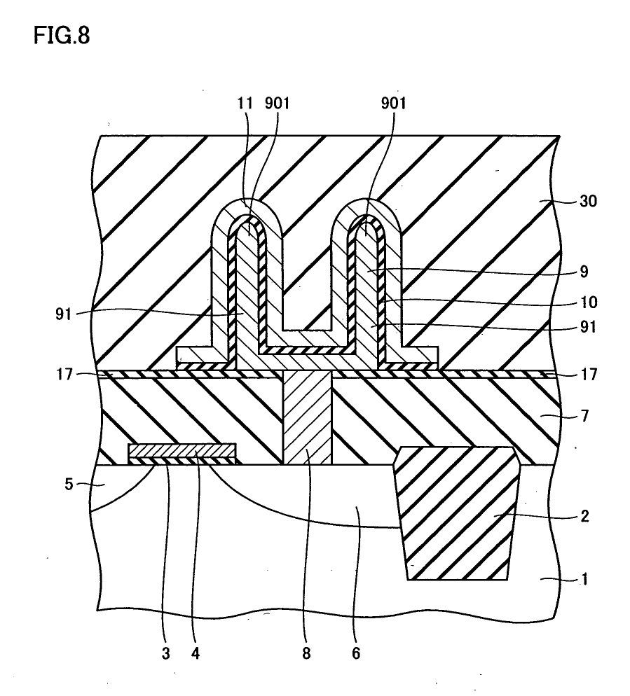

Now, a semiconductor device according to a second embodiment and method for manufacturing the same will be described with reference to FIGS. 8 to 13. First, a structure of a semiconductor device according to the present embodiment is described with reference to FIG. 8. As shown in FIG. 8, a semiconductor device according to the present embodiment has substantially the same structure of the semiconductor device according to the first embodiment.

A comparison of FIGS. 1 and 8 shows that the only difference is the shape of top end 901 of vertical portion 91 of the capacitor bottom electrode of a cylindrical capacitor, which extends perpendicularly to the main surface of a semiconductor substrate 1. The present embodiment uses ruthenium as the material of capacitor bottom electrode 9. In FIG. 8, top end 901 of vertical portion 91 is not pointed, which allows capacitor dielectric film 10 to have in general a width that is substantially uniform. That is, capacitor dielectric film 10 has a uniform film thickness, and capacitor bottom electrode 9 does not have a portion with an extreme concentration of electric field. This provides improved reliability of a capacitor. Further, the semiconductor device according to the present embodiment as shown in FIG. 8 does not have dielectric film 100 of FIG. 1. That is, capacitor dielectric film 10 is made of one type of film. It should be noted that the semiconductor device according to the second embodiment has exact the same structure as the first embodiment except for the structural features described above, and will not be described again.

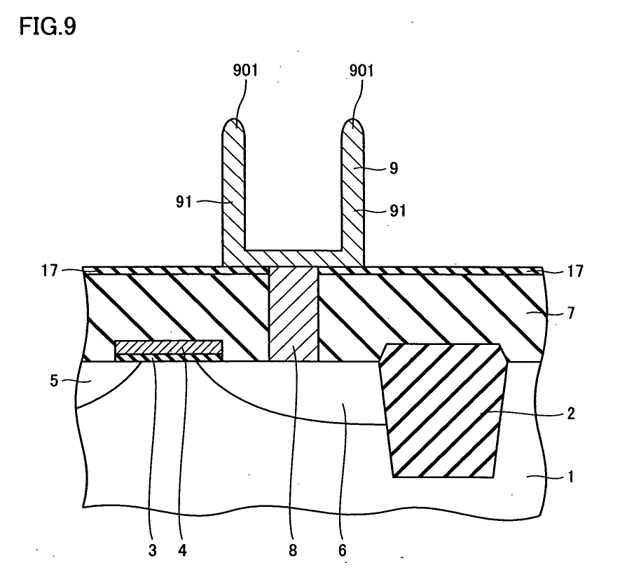

A method for manufacturing a structure of a semiconductor device according to the present embodiment as described above will be described with reference to FIGS. 9 to 13.

In a method for manufacturing a semiconductor device according to the present embodiment, exactly the same manufacturing steps are performed as those for the semiconductor device according to the first embodiment until capacitor bottom electrode 9 of FIG. 4 is formed. Accordingly, in the method for manufacturing a semiconductor device according to the present embodiment, too, a film that is to be capacitor bottom electrode 9 has, for the time being, a pointed shape formed on top end 901 of its vertical portion 91, as illustrated in FIG. 4. Thereafter, the pointed portion shown in FIG. 9 will be treated to have a rounded smooth surface.

A method for treating the pointed portion to form a rounded smooth shape is as follows:

Initially, a semiconductor device with a structure as shown in FIG. 4, which is still in the process of formation, is put into a vessel. A reducing environment, which is an atmosphere of approximately 100% hydrogen, is maintained within the vessel. In this atmosphere of hydrogen, annealing is performed on the film that is to be capacitor bottom electrode 9 of the semiconductor device as shown in FIG. 4, which is still in the process of formation, at a temperature from 500 to 950° C. for a minute or longer. The pressure within the vessel is adjusted to range from 1 Torr (≈133.32 pascals) to atmospheric pressure. “Atmospheric pressure” means a value around 1013 hectopascals including a pressure in the range of 5% more or less than that, i.e. a condition of pressure where no extra pressure is applied.

An annealing under such conditions causes capacitor bottom electrode 9 of ruthenium to be melted by heat, such that the pointed portion becomes rounded. In this way, capacitor bottom electrode 9 with the structure of FIG. 9 is formed.

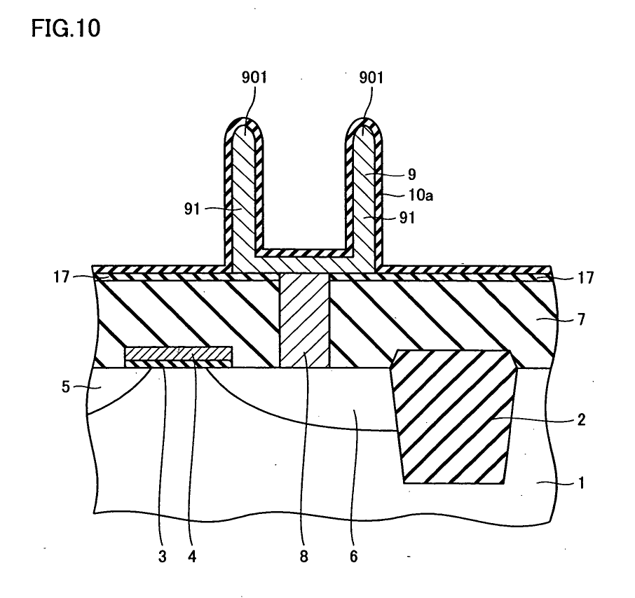

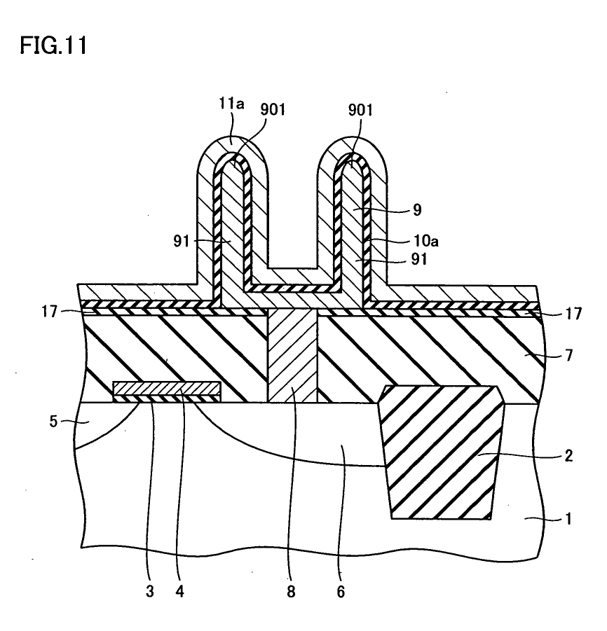

Next, as shown in FIG. 10, dielectric film 10a is formed to cover the 1surface of capacitor bottom electrode 9 and that of silicon nitride film 17. Conductive layer 11a is then formed upon dielectric film 10a, as shown in FIG. 11. Thereafter, dielectric film 10a and conductive layer 11a are etched by exactly the same method as is used to form a capacitor according to the first embodiment. This produces a capacitor including capacitor bottom electrode 9, capacitor dielectric film 10 and capacitor top electrode 11. The capacitor is then embedded in interlayer insulation film 30. This provides a semiconductor device having a structure as shown in FIG. 8.

In a method for manufacturing a semiconductor device according to the present embodiment as described above, annealing is performed in a prescribed condition on a semiconductor device as shown in FIG. 4, which is still in the process of formation. As a result, the portion with a pointed shape at the top of the film that is to be capacitor bottom electrode 9 of FIG. 4 becomes rounded. Accordingly, capacitor dielectric film 10 formed on the surface of capacitor bottom electrode 9 has a uniform thickness, while capacitor bottom electrode 9 can be free of a portion with a possible concentration of electric field. Thus, leakage current is less likely to occur in capacitor dielectric film 10, resulting in improved property of a semiconductor device.

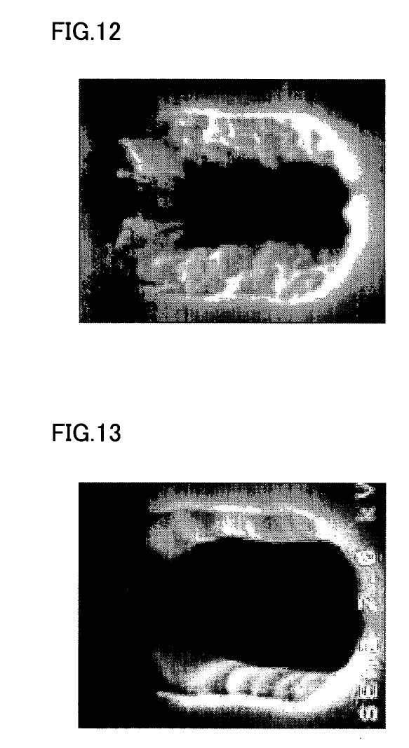

FIG. 12 is a photographic picture showing an upper surface of a capacitor bottom electrode of a cylindrical capacitor that has been formed without using the step of annealing, used in the method for manufacturing a semiconductor device according to the present embodiment. FIG. 13 is a photographic picture showing an upper surface of capacitor bottom electrode 9 of a cylindrical capacitor that has been produced by a method for manufacturing a semiconductor device with the step of annealing according to the present embodiment. As shown by a comparison between FIGS. 12 and 13, the method for manufacturing a semiconductor device according to the present embodiment allows top end 901 of vertical portion 91 of capacitor bottom electrode 9 to have a more rounded shape than does the method for manufacturing the semiconductor device without the step of annealing used in a method for manufacturing a semiconductor device of the second embodiment.

Third Embodiment

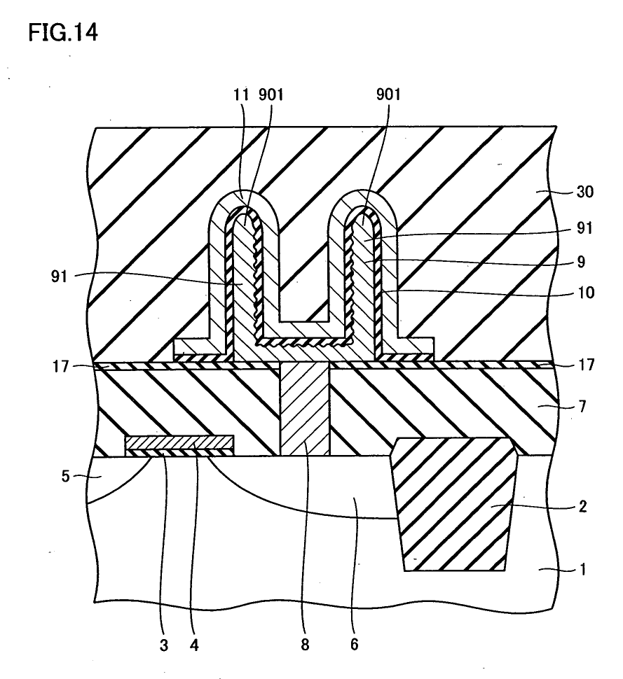

Now, a structure of a semiconductor device according to a third embodiment and a method for manufacturing it will be described with reference to FIGS. 14 to 22. First, a structure of a semiconductor device according to the present embodiment is described referring to FIG. 14. The structure of the semiconductor device according to the third embodiment is substantially the same as that of the semiconductor device of the second embodiment shown in FIG. 8: top end 901 of vertical portion 91 of capacitor bottom electrode 9 has a smooth curved surface. In the semiconductor device according to the present embodiment, however, the side and bottom of the hole defined by capacitor bottom electrode 9 have a smooth and curved surface, as well. In other respects, the structure of the semiconductor device according to the third embodiment is exactly the same as that of a semiconductor device according to the second embodiment, and will not be described again for those parts.

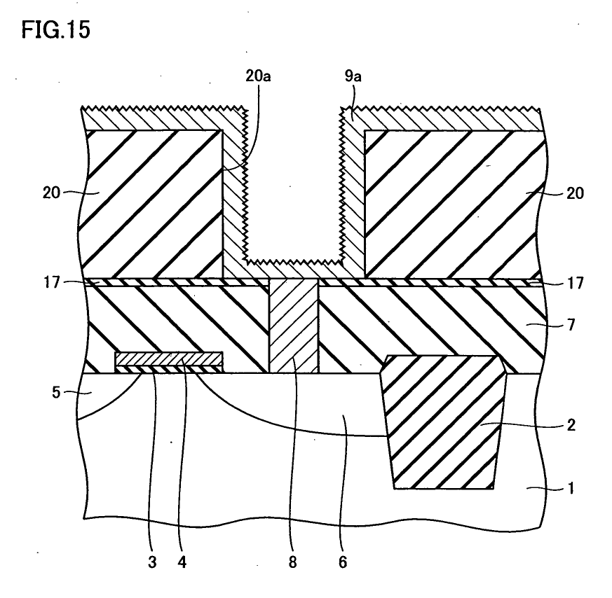

Next, a method for manufacturing a semiconductor device according to the present embodiment will be described with reference to FIGS. 15 to 20.

First, the structure of FIG. 15 is described. The same steps used for methods for manufacturing a semiconductor device according to the first and second embodiments are performed until silicon nitride film 17 is formed, as in the structure of FIG. 15. Then, an interlayer insulation film (silicon oxide) 20 is formed upon silicon nitride film 17. Thereafter, a hole 20a is made that penetrates interlayer insulation film 20 from top to bottom, exposing a surface of contact plug 8.

Conductive layer 9a of ruthenium is then formed on the side and bottom of hole 20a and over the top surface of interlayer insulation film 20. MOCVD (Metal Organic Chemical Vapor Deposition) is used for the step of forming conductive layer 9a of ruthenium. Conductive layer 9a of ruthenium formed by means of MOCVD has irregularities with pointed tips on its surface. This is because a mixed gas of ruthenium precursor and oxygen is used to form conductive layer 9a, resulting in conductive layer 9a containing a considerable amount of ruthenium dioxide (RuO₂). Ruthenium dioxide has a needle-like crystal structure, compromising significantly the evenness of the surface of conductive layer 9a.

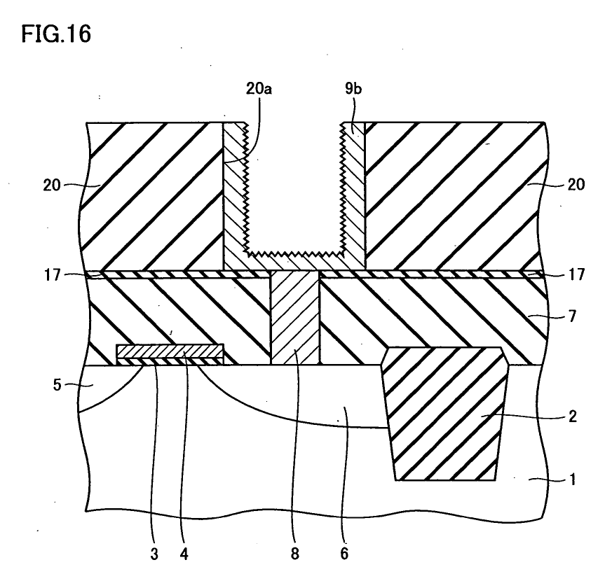

Conductive layer 9a of ruthenium is then removed by CMP (Chemical Mechanical Polishing), exposing the top surface of interlayer insulation film 20. This leaves conductive layer 9b only on the side and bottom of hole 20a, as shown in FIG. 16. There still remain irregularities with pointed tips on the side and bottom of the hole defined by conductive layer 9b.

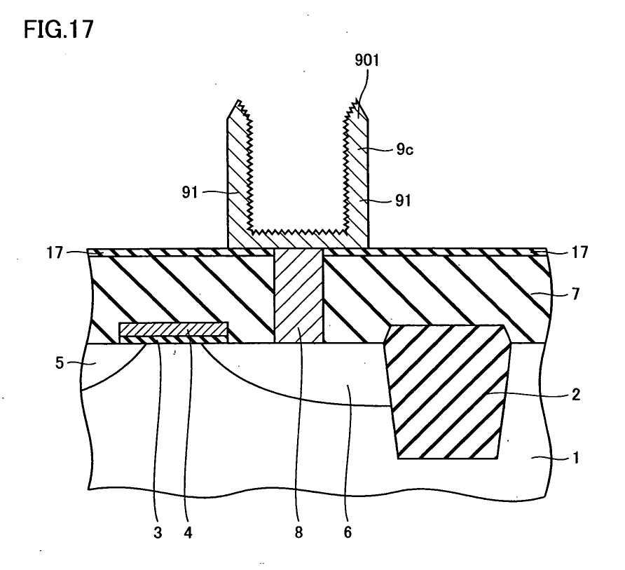

Then, interlayer insulation film 20 made of silicon oxide film is wet-etched using hydrofluoric acid. Silicon nitride film 17 and conductive layer 9c are not etched away and remain after this step, resulting in a structure as shown in FIG. 17.

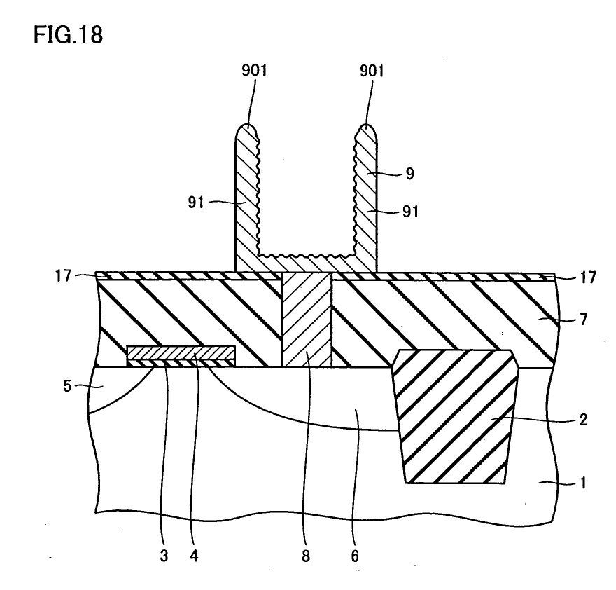

In the structure of FIG. 17, conductive layer 9c that will eventually be a capacitor bottom electrode has been formed. Conductive layer 9c is the result of removing top end 901 of vertical portion 91 of conductive layer 9b, which produces a pointed shape. Irregularities with pointed tips have been formed on the side and bottom of the hole defined by this conductive layer 9c. The step of annealing conductive layer 9c is then performed, causing the pointed top end of the vertical portion of conductive layer 9c of FIG. 17 to be melted by heat. As a result, top end 901 of vertical portion 91 of conductive layer 9c has a rounded shape, as shown in FIG. 18.

The step of annealing conductive layer 9c is performed in a reducing environment, i.e. an atmosphere of approximately 100% hydrogen at a temperature ranging from 650 to 950° C. under a pressure ranging from 1 Torr to atmospheric pressure for a minute or longer. Here, ruthenium dioxide contained in capacitor bottom electrode 9 is reduced, thereby producing metallic ruthenium. As a result, pointed tips of irregularities of the surface of the hole defined by capacitor bottom electrode 9 become rounded.

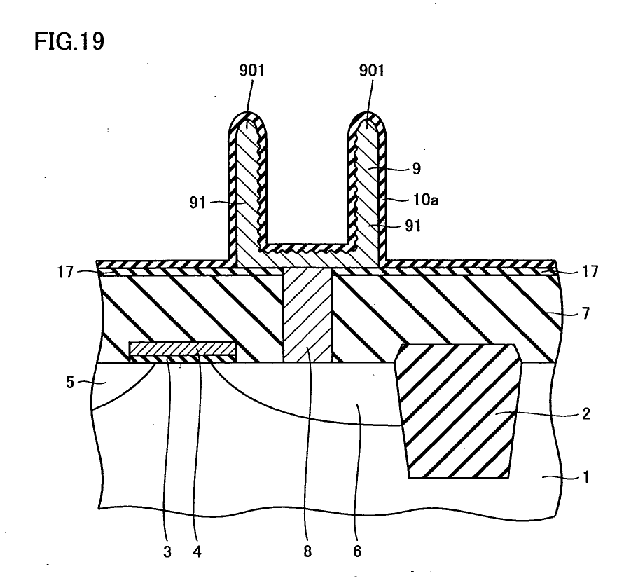

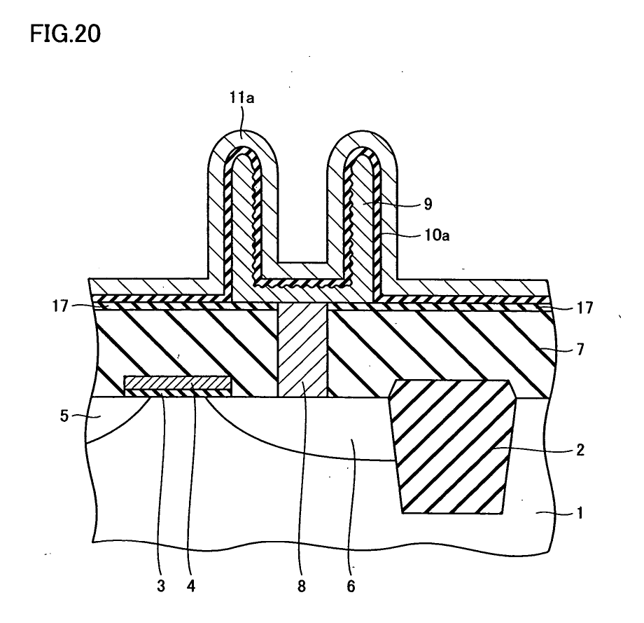

Referring to FIG. 19, dielectric film 10a is then formed to cover the surface of capacitor bottom electrode 9 and that of silicon nitride film 17. Next, as shown in FIG. 20, conductive layer 11a is formed to cover the surface of dielectric film 10a. Thereafter, the step of forming interlayer insulation fm 30 is performed as in methods for manufacturing a semiconductor device according to the first and second embodiments, thereby forming a semiconductor device with a capacitor including capacitor bottom electrode 9, capacitor dielectric film 10 and capacitor top electrode 11 as shown in FIG. 14.

In a method for manufacturing a semiconductor device according to the present embodiment as described above, referring to FIG. 17, conductive layer 9c that is to be capacitor bottom electrode 9 of ruthenium is annealed in a reducing environment. Thus, irregularities with pointed tips formed on the side and bottom of the hole defined by conductive layer 9c, and a pointed shape formed on top end 901 of vertical portion 91 of conductive layer 9c acquire a rounded and smooth curved surface, that is, irregularities with curved tips.

As a result, in a capacitor with an ultimate structure as shown in FIG. 14, the top end of the vertical portion, the inner side and bottom of the hole of capacitor bottom electrode 9 do not have a portion where concentration of electric field can occur. Thus, leakage current is less likely to occur in capacitor dielectric film 10, thereby improving a property of a semiconductor device.

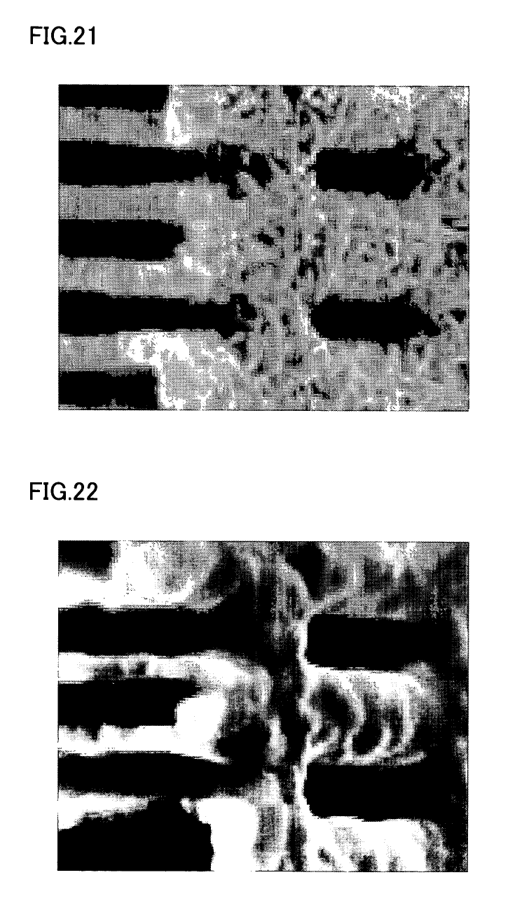

FIG. 21 is a photographic picture showing an upper surface of a capacitor bottom electrode that has been formed without using the step of annealing of the present embodiment. FIG. 22 is a phonographic picture showing an upper surface of a capacitor bottom electrode after the step of annealing of the method for manufacturing a semiconductor device according to the present embodiment. As shown by a comparison between FIGS. 21 and 22, capacitor bottom electrode 9 formed by the method for manufacturing a semiconductor device according to the present embodimnent is different from a capacitor bottom electrode that has been formed without annealing in that a pointed shape has not been formed on top end 901 of vertical portion 91 of capacitor bottom electrode 9, and irregularities with pointed tips have not been formed on the side and bottom of the hole of capacitor bottom electrode 9.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a semiconductor substrate;
a capacitor lower electrode having a vertical portion extending substantially perpendicularly to a main surface of said semiconductor substrate;
a capacitor dielectric film covering a surface of said vertical portion;
a capacitor upper electrode covering a surface of said capacitor dielectric film,
a film thickness of a portion of said capacitor dielectric film formed on top of said vertical portion being greater than a film thickness of a portion of said capacitor dielectric film formed on a side of said vertical portion.

2. The semiconductor device of claim 1, wherein said capacitor dielectric film has a two-layer structure for the portion formed on top of said vertical portion.

3. The semiconductor device of claim 2, wherein said two-layer structure is formed of two types of insulation film different in composition.

4. A method for manufacturing a semiconductor device, comprising the steps of:
above a semiconductor substrate, forming a film to be a capacitor lower electrode having a vertical portion extending perpendicularly to a main surface of said semiconductor substrate;
forming a film to be a capacitor dielectric film to cover a surface of said vertical portion;
adhering an additional dielectric film on a surface of said film to be said capacitor dielectric film above said vertical portion by sputtering or plasma chemical vapor deposition of a dielectric from above said film to be said capacitor dielectric film; and
forming a film to be a capacitor top electrode to cover a surface of said film to be said capacitor dielectric film and a surface of said additional dielectric film.

5. A method for manufacturing a semiconductor device, comprising the steps of:
above a semiconductor substrate, forming a film to be a capacitor lower electrode made of ruthenium having a vertical portion extending substantially perpendicularly to a main surface of the semiconductor substrate;
annealing said film to be a capacitor lower electrode in a reducing environment at a temperature ranging from 500 to 950° C. under a pressure ranging from 1 Torr to atmospheric pressure for at least one minute;
forming a film to be a capacitor dielectric film to cover a surface of said capacitor lower electrode annealed; and
forming a film to be a capacitor upper electrode to cover a surface of said film to be said capacitor dielectric film.

6. A method for manufacturing a semiconductor device, comprising the steps of:
forming an interlayer insulation film above a semiconductor substrate;
making a hole penetrating said interlayer insulation film from top to bottom;
forming a film to be a capacitor lower electrode of ruthenium on a side of said hole by metal organic chemical vapor deposition;
removing said interlayer insulation film to leave said film to be said capacitor bottom electrode;
annealing said film to be said capacitor bottom electrode in a reducing environment at a temperature ranging from 650 to 950° C. under a pressure ranging from 1 Torr to atmospheric temperature for at least one minute;
forming a film to be a capacitor dielectric film to cover a surface of said film annealed to be said capacitor lower electrode; and
forming a film to be a capacitor top electrode to cover a surface of said film to be said capacitor dielectric film.
